(19) United States
(12) Patent Application Publication
(10) Pub. No.: US 2024/0255447 A1
(43) Pub. Date: Aug. 1, 2024

(54) ELECTRON DIFFRACTION SYSTEM FOR CHARACTERIZING NANOCRYSTALLINE STRUCTURES

(71) Applicant: Eldico Scientific AG, Villigen (CH)

(72) Inventors: Francesco Garbuglia, Schindellegi (CH); Gustavo Santiso-Quinones, Birkingen (DE); Laura Samperisi, Basel (CH); Danny Taminiau, Venray (NL); Nico Tan, Eindhoven (NL)

(21) Appl. No.: 18/429,073

(22) Filed: Jan. 31, 2024

Related U.S. Application Data
(60) Provisional application No. 63/442,316, filed on Jan. 31, 2023.

(51) Int. Cl. G01N 23/20058; G01N 23/20008

(52) U.S. Cl. CPC G01N 23/20058; G01N 23/20008

(57) ABSTRACT

One variation of a system includes: a housing configured to hold a vacuum; a primary assembly; and a cooling assembly. The primary assembly includes: a sample receiver including a base section and a sample holder mounted to the base section and configured to transiently receive and retain a sample specimen; a receiver platform configured to receive and support the sample receiver; and a set of positioner stages flexibly coupled to the receiver platform and configured to transiently drive the sample holder to locate the sample specimen in a position intersecting an electron pathway. The cooling assembly includes: a cold finger defining an end submerged in a volume of coolant; and a conductive cooling braid coupled to the cold finger and to the primary assembly; and configured to communicate heat from the primary assembly into the cold finger to cool the sample specimen to temperatures within a target sample temperature range.

### CROSS-REFERENCE TO RELATED APPLICATIONS

This application claims the benefit of U.S. Provisional Application No. 63/442,316, filed on 31 Jan. 2023, which is incorporated in its entirety by this reference.

### TECHNICAL FIELD

This invention relates generally to the field of electron diffraction and more specifically to a new and useful system for characterizing nanocrystalline systems in the field of electron diffraction.

### BRIEF DESCRIPTION OF THE FIGURES

FIG. 1 is a schematic representation of a system;

FIG. 2 is a schematic representation of one variation of the system; and

FIGS. 3A and 3B are schematic representation of one variation of the system.

### DESCRIPTION OF THE EMBODIMENTS

The following description of embodiments of the invention is not intended to limit the invention to these embodiments but rather to enable a person skilled in the art to make and use this invention. Variations, configurations, implementations, example implementations, and examples described herein are optional and are not exclusive to the variations, configurations, implementations, example implementations, and examples they describe. The invention described herein can include any and all permutations of these variations, configurations, implementations, example implementations, and examples.

### 1. System

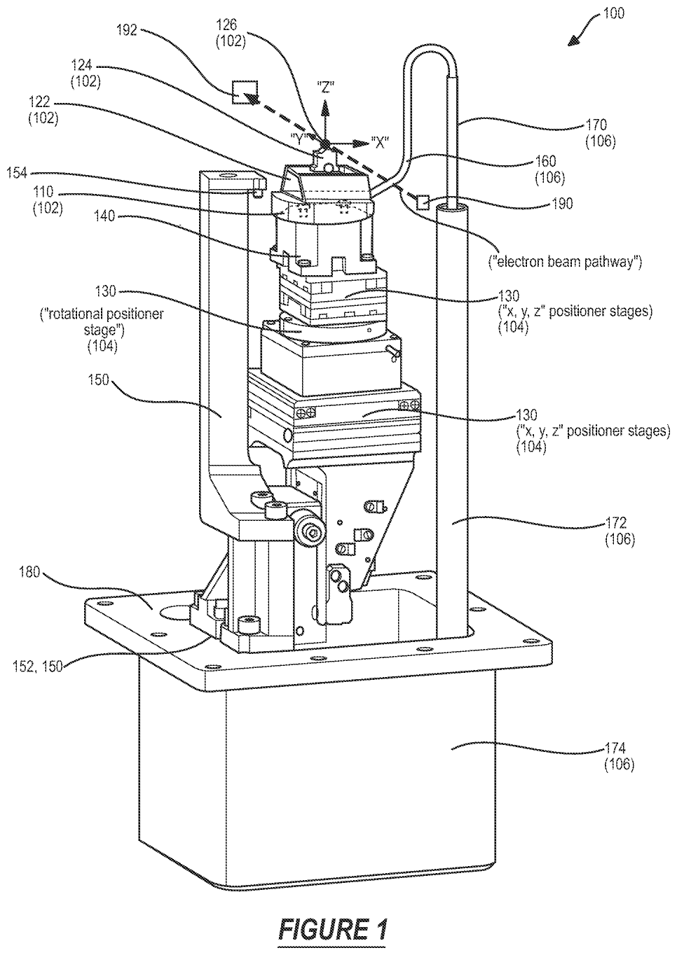

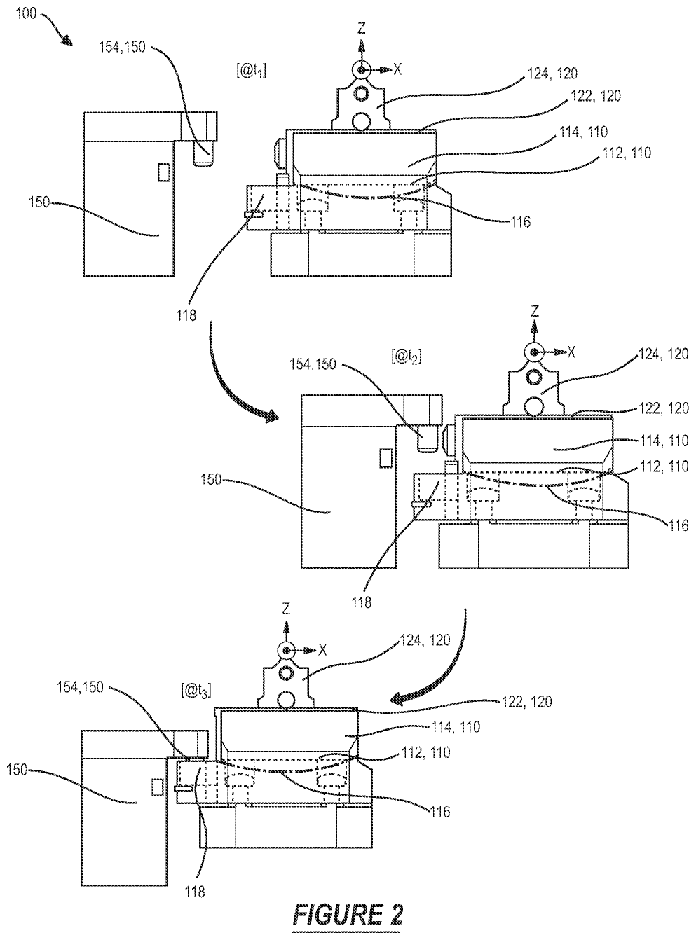

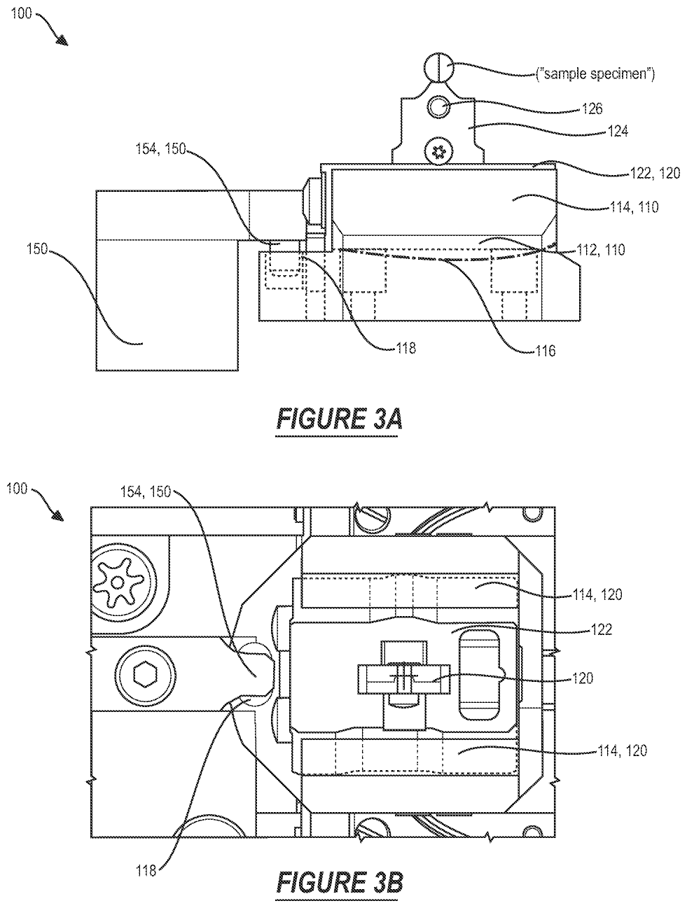

As shown in FIGS. 1, 2, 3A and 3B, a system 100 includes: a housing 180 configured to hold a vacuum; a primary assembly arranged within the housing 180; and a cooling assembly 106 thermally-coupled to the primary assembly.

The primary assembly includes: a sample receiver 120; a receiver platform 110; and a set of positioner stages 130.

The sample receiver 120 includes: a base section 122 defining an upper surface; and a sample holder 124 rigidly mounted to the upper surface of the base section 122 and defining a grid receptacle 126 configured to transiently receive and retain a sample grid preloaded with a sample specimen.

The receiver platform 110: defines a mounting surface configured to slidably receive and support the sample receiver 120; and includes a set of fixed rails 114 extending from the mounting surface and configured to retain the sample receiver 120 against the mounting surface.

The set of positioner stages 130: are flexibly coupled to the receiver platform 110; and are configured to drive the sample holder 124 to a sequence of positions in order to locate the sample specimen in a target detection position intersecting an electron pathway of an electron emitter 190 configured to transiently generate and accelerate an electron beam along the electron beam pathway (toward the sample grid).

The cooling assembly 106 includes: a storage vessel 174 containing a volume of coolant; a cold finger 170; and a cooling braid 160.

The cold finger 170: extends through a vacuum pipe 172 configured to hold the cold finger 170 under vacuum; and defines a first end submerged in the volume of coolant and a second end, opposite the first end, arranged external the storage vessel 174.

The cooling braid 160: includes a flexible, conductive material; is coupled to the cold finger 170 and to the primary assembly; and is configured to communicate thermal energy from the primary assembly into the cold finger 170 to cool the sample specimen, loaded within the grid receptacle 126, to temperatures within a target sample temperature range.

One variation of the system 100 includes: a housing 180 configured to hold a vacuum; an upper assembly 102 arranged within the housing 180; a lower assembly 104 flexibly coupled to the upper assembly 102; and a cooling assembly 106 thermally-coupled to the upper assembly 102.

In this variation, the upper assembly 102 includes: a sample receiver 120 including: a base section 122 defining an upper surface and a lower surface opposite the upper surface; a sample holder 124 rigidly mounted to the upper surface of the base section 122 and defining a grid receptacle 126 configured to transiently receive and retain a sample grid preloaded with a sample specimen; receiver platform 110 configured to transiently receive and support the sample receiver 120 on a mounting surface and between a set of fixed rails 114 extending from the mounting surface; and a spring element 116 arranged proximal the mounting surface and configured to exert a spring force on the mounting surface to drive the mounting surface against a lower surface of the base section 122 and drive the receiver platform 110 upward into the set of fixed rails 114.

In this variation, the lower assembly 104 includes a set of positioner stages 130 configured to transiently actuate the receiver platform 110 to drive the sample holder 124 to a sequence of positions in order to locate the sample specimen in a target detection position intersecting an electron pathway of an electron emitter 190.

In this variation, the cooling assembly 106 includes: a storage vessel 174 containing a volume of coolant; a cold finger 170 defining a first end submerged in the volume of coolant and a second end, opposite the first end, arranged external the storage vessel 174; and a cooling braid 160. The cooling braid 160: includes a conductive material; is thermally-coupled to the cold finger 170 and to the upper assembly 102; and is configured to communicate thermal energy from the upper assembly 102 into the cold finger 170 to cool the sample specimen, loaded within the grid receptacle 126, to temperatures within a target sample temperature range.

One variation of the system 100 further includes: an electron emitter 190 configured to generate and accelerate an electron beam along an electron beam pathway defined by electron optics and extending from an outlet of the electron emitter 190 to the sample target detection position; and a set of detectors 192 configured to capture a set of sample data—responsive to actuation of the electron emitter 190—representing structural characteristics of the sample loaded in the grid receptacle 126.

In one variation of the system 100, the receiver platform 110: defines a recess 118 arranged on the mounting surface; and is configured to receive the sample receiver 120 on the mounting surface during a loading period. In this variation, the primary assembly includes: an upper assembly 102 including the sample receiver 120 and the receiver platform 110; and a lower assembly 104 including the set of positioner stages 130. In this variation, the lower assembly 104 includes a positioner base 152 and the set of positioner stages 130 flexibly mounted to the positioner base 152. In this variation, the system 100 can further include a positioner arm 150 rigidly mounted to the positioner base 152 and defining a fixed pin 154 configured to transiently engage the recess 118 of the receiver platform 110 to stabilize the receiver platform 110 during the loading period.

### 1.1 System: Cooling Braid+Upper Assembly

One variation of the system 100 includes: a housing 180 configured to hold a vacuum; an upper assembly 102 arranged within the housing 180; a lower assembly 104 arranged within the housing 180; and a cooling assembly 106 thermally-coupled to the upper assembly 102.

The upper assembly 102 includes: a sample receiver 120 including a base section 122 defining an upper surface and a sample holder 124—rigidly mounted to the upper surface of the base section 122—defining a grid receptacle 126 configured to transiently receive and retain a sample grid preloaded with a sample specimen; and a receiver platform 110—defining a mounting surface configured to slidably receive and support the sample receiver 120—including a set of fixed rails 114 extending from the mounting surface and configured to retain the sample receiver 120 against the mounting surface.

The lower assembly 104 includes a set of positioner stages 130 flexibly coupled to the receiver platform 110 and configured to drive the sample holder 124 to a sequence of positions in order to locate the sample specimen in a target detection position intersecting an electron pathway of an electron emitter 190.

The cooling assembly 106 is thermally-coupled to the upper assembly 102 and includes: a storage vessel 174 containing a volume of coolant; a cold finger 170 extending through a vacuum chamber and defining a first end submerged in the volume of coolant; and a cooling braid 160. The cooling braid 160: includes a flexible, conductive material; defines a second end coupled to the cold finger 170 and a third end coupled to the upper assembly 102; and is configured to communicate thermal energy from the upper assembly 102 into the cold finger 170 to cool the sample specimen, loaded within the grid receptacle 126, to temperatures within a target sample temperature range.

In this variation, the system 100 can further include an insulator section 140: interposed between the upper assembly 102 and the lower assembly 104; including a material exhibiting a conductivity less than a threshold conductivity; and configured to thermally isolate the upper assembly 102 from the lower assembly 104.

One variation of the system 100 includes: a housing 180 (e.g., a thermal shroud) configured to hold a high vacuum; an upper assembly 102 including a sample receiver 120 and a receiver platform 110; a lower assembly 104 including a set of positioner stages 130; an insulator section 140; and a cooling assembly 106 thermally-coupled to the upper assembly 102.

The upper assembly 102 is arranged within the housing 180 and includes: a sample receiver 120; and a receiver platform 110 configured to transiently receive the sample receiver 120 on a platform surface of the receiver platform 110. The sample receiver 120 includes: a base section 122 defining an upper surface; and a sample holder 124 rigidly mounted to the upper surface of the base section 122 and defining a grid receptacle 126 configured to transiently receive and retain a sample grid preloaded with a sample specimen. The receiver platform 110: is rigidly fixed to the insulator section 140; defines a mounting surface configured to receive and support the sample receiver 120; and includes a set of fixed rails 114 extending from the mounting surface and configured to retain the sample receiver 120 on the mounting surface.

The lower assembly 104 is flexibly coupled to the upper assembly 102, arranged within the housing 180, and includes a set of positioner stages 130 (e.g., x, y, and z positioner stages 130) configured to drive the sample holder 124 to a sequence of positions in order to locate the sample specimen—retained by the grid receptacle 126 of the sample holder 124—in a sample target detection position.

The insulator section 140 is arranged between the upper assembly 102 and the lower assembly 104 and configured to thermally isolate the upper assembly 102 from the lower assembly 104.

The cooling assembly 106 includes: a storage vessel 174 containing a volume of coolant (e.g., liquid nitrogen); a cold finger 170 (e.g., a copper bar) defining a first end inserted in the volume of coolant within the storage vessel 174 and defining a second end external the storage vessel 174; a vacuum pipe 172 encompassing a portion of the cold finger 170, external the storage vessel 174, and configured to maintain a vacuum within the vacuum pipe 172; and a cooling braid 160 thermally-coupled to the cold finger 170 and to the sample holder 124 and configured to cool the upper assembly 102 and the sample specimen to temperatures within a target sample temperature range.

### 2. Applications

Generally, the system 100 includes: a high-vacuum housing 180 configured to hold components of the system 100 under a high-vacuum in order to restrict heat transfer via convection while enabling heat transfer via conduction within the housing 180; an upper assembly 102—including a sample receiver 120 and a receiver platform 110—configured to locate a sample specimen within the housing 180; a set of positioner stages 130 mechanically coupled to the upper assembly 102 and configured to locate the sample specimen in a series of angular positions, at a target detection position, relative an electron emitter 190 configured to generate and accelerate an electron beam through the sample and a set of detectors 192 configured to record electromagnetic signals generated by the sample responsive to contact with the electron beam; and a cooling assembly 106—including a cooling braid 160 thermally-coupled to the upper assembly 102 and a volume of coolant (e.g., liquid nitrogen)—configured to cool the upper assembly 102, including the sample, to temperatures within a target sample temperature range (e.g., between −140 degrees Celsius and −180 degrees Celsius) prior to activation of the electron emitter 190.

In particular, the set of positioner stages 130 can be configured to accurately locate the sample at this target detection position in order to enable accurate characterization of structural characteristics—such as images, diffraction patterns, and/or electron energy loss spectra—of the sample specimen based on electromagnetic data collected during actuation of the electron emitter 190. Further, the cooling assembly 106 can be configured to cool the sample specimen to temperatures within the target temperature range and within a threshold cooling duration, in order to stabilize the sample specimen—and thus enable characterization of the sample structure—while enabling relatively high throughput of samples due to rapid cooling of the sample specimen.

By locating these assemblies within the high-vacuum housing 180, the system 100 can constrain all heat transfer within this housing 180 to heat transfer via conduction (e.g., with limited or negligible heat transfer due to radiation) and therefore enable increased temperature control within the housing 180 via contact between the upper assembly 102 and cooling assembly 106 and thermal isolation of the lower assembly 104.

In one implementation, the cooling assembly 106 can include: a flexible, conductive, cooling braid 160 coupled to the upper assembly 102 (e.g., at the receiver platform 110); and a cooling finger coupled to the cooling braid 160 at a first end and coupled to (e.g., submerged within) a volume of coolant—held at temperatures within the target sample temperature range—at a second end. The cooling finger can be configured to cool the cooling braid 160 via conduction, and the cooling braid 160 can in turn extract heat from the upper assembly 102 via conduction, thereby cooling the sample loaded in the sample holder 124. In this implementation, the cooling assembly 106 is therefore configured to cool only the upper assembly 102—thermally isolated from the set of positioner stages 130 via an insulator section 140 arranged between the receiver platform 110 and the set of positioner stages 130—thereby significantly reducing the cooling duration for cooling the sample while increasing stability of the system 100 by only requiring cooling of a portion of the system 100.

Further, the cooling braid 160—physically and thermally—coupled to the upper assembly 102—can be configured to: exhibit high thermal conductivity, thereby enabling a high rate of cooling of the sample loaded within the sample holder 124; and high flexibility at low temperatures (e.g., below −100 degrees Celsius) within the target sample temperature range, thereby enabling relocation and rotation of the upper assembly 102 with minimal fatigue and/or breakage experienced by the cooling braid 160 and with little to no torque applied to the upper assembly 102 by the cooling braid 160 against the set of positioner stages 130.

The flexible, conductive, cooling braid 160 can therefore be configured to: experience temperature cycling over many sampling cycles (e.g., for each sample) with minimal breakage and/or material fatigue, thereby increasing a shelf life of the cooling braid 160 and/or reducing costs and downtime due to maintenance or replacement of the cooling braid 160; and enable accurate positioning of the sample relative the electron emitter 190 without interference due to forces applied by the cooling braid 160 on the upper assembly 102, thereby increasing accuracy of detection and enabling rapid placement of the sample at the target detection position.

Further, the system 100 can include an insulator section 140: arranged between the upper assembly 102—including the sample holder 124 preloaded with the sample specimen—and the lower assembly 104 including the set of positioner stages 130; and configured to prevent heat transfer from the set of positioner stages 130 into the upper assembly 102—such as due to heat generation during actuation of these positioner stages 130—and therefore prevent destabilization of the sample specimen and/or increased cooling duration due to heating of the upper assembly 102 by the lower assembly 104.

### 3. High-Vacuum Housing

Generally, the system 100 includes a housing 180 configured to hold a high vacuum and thus locate components of the system 100 within a high-vacuum internal volume of the housing 180.

The housing 180 can define an internal volume-containing the upper assembly 102, the lower assembly 104, and the cooling assembly 106—exhibiting high vacuum, thereby limiting and/or preventing heat transfer via convection within the housing 180. Therefore, by maintaining this internal volume of the housing 180 under high vacuum, the system 100 can constrain heat transfer between components of the system 100 within the housing 180 to heat transfer via conduction and radiation. However, heat transfer via radiation may be negligible, such as below a detectable threshold. Therefore, the system 100 can regulate thermal fluctuations of components within the housing 180 by regulating heat transfer via conduction between contacting surfaces of components within the housing 180.

In one implementation, the system 100 can include an ion pump configured to maintain a vacuum within the internal volume of the housing 180. For example, the system 100 can include: the housing 180 configured to hold a vacuum within the interior volume of the housing 180 in order to limit heat transfer via convection within the interior volume; and an ion pump—fluidly coupled to the internal volume of the housing 180—configured to ionize particles (e.g., atoms, molecules) within the housing 180 and then draw these ionized particles from within the housing 180 and onto a set of (e.g., one or more) charged plates of the ion pump, thereby generating and/or maintaining the vacuum within the internal volume of the housing 180.

### 3.1 Upper Assembly

The system 100 includes a primary assembly-including an upper assembly 102 and a lower assembly 104 flexibly coupled to the upper assembly 102—arranged within the housing 180.

Generally, the upper assembly 102 includes a sample receiver 120—including a sample holder 124—and a sample platform configured to transiently receive the sample receiver 120 on a surface of the sample platform.

In particular, the sample receiver 120 includes: a base section 122; and a sample holder 124 rigidly mounted to an upper surface of the base section 122 (e.g., in a center of the upper surface) and defining a grid receptacle 126 configured to transiently receive and retain a sample grid preloaded with a sample. The receiver platform 110: is slidably coupled to the sample receiver 120 and rigidly mounted to the insulator section 140 opposite the lower assembly 104 including the set of positioner stages 130; and defines a mounting surface configured to transiently receive and mate with a base surface of the sample receiver 120 in a loaded position. The receiver platform 110 and the sample holder 124 can therefore cooperate to locate the sample grid—preloaded with the sample—within the high-vacuum housing 180 and to mechanically couple the sample holder 124 to the set of positioner stages 130 arranged below the upper assembly 102 (e.g., opposite the insulator section 140).

### 3.1.1 Sample Receiver

Generally, the upper assembly 102 includes a sample receiver 120 removably coupled to the receiver platform 110. The sample receiver 120 can include: a base section 122 defining an upper surface; and a sample holder 124—rigidly mounted to the upper surface of the base section 122—defining a grid receptacle 126 configured to transiently receive and retain a sample grid preloaded with a sample specimen (hereinafter a “sample”).

In one implementation, the sampler holder: defines a bottom surface-such as a substantially flat surface—mounted flush to the upper surface of the base section 122; and is configured to receive a section of the sample grid within the grid receptacle 126 to locate the sample—loaded in a central region of the sample grid—in a target sample position seated above the sampler holder opposite the base section 122.

For example, a user may initially load the sample within the sample grid (e.g., a TEM grid)—such as a thin disc including a mesh configured to support sample specimen and enable flow of electrons through the mesh—defining a sample loading region and an outer perimeter arranged about the sample loading region. The sample holder 124 can define a narrow grid receptacle 126, arranged on a top surface of the sample holder 124, configured to receive and clamp a small section (e.g., a 0.1 mm² section, a 0.2 mm² section) of the outer perimeter of the sample grid to rigidly retain the sample grid within the grid receptacle 126 and locate the sample loading region—preloaded with the sample by the user—in the target sample position seated over the top surface of the sample holder 124. The sample holder 124 can be rigidly mounted (e.g., bolted) to the upper surface of the base section 122. In this example, the upper surface of the base section 122 and the bottom surface of the sample holder 124 can cooperate to define a contact area exceeding a threshold area configured to enable substantial heat transfer—such as at a threshold or target rate-between the sample holder 124 and the base section 122.

### 3.1.2 Receiver Platform

The upper assembly 102 can include a receiver platform 110: rigidly fixed to the insulator section 140; defining a mounting surface (e.g., a flat and/or smooth surface) configured to receive and support the sample receiver 120; and including a set of fixed rails 114—each fixed rail, in the set of fixed rails 114, defining an undercut section in a set of undercut sections-extending from the mounting surface. For example, the first and second undercut sections of the first and second fixed rail 114 can define complementary 45-degree beveled faces configured to seat over the mounting surface of the receiver platform 110. Generally, the receiver platform 110 can be configured to slidably receive the sample receiver 120 on the mounting surface and between the set of fixed rails 114.

In one implementation, the set of fixed rails 114 can be configured to transiently mate with complementary features of the base section 122 of the sample receiver 120 to locate the sample receiver 120 on the mounting surface and constrain rotation, lateral motion, and/or perpendicular motion (e.g., outward motion) of the sample receiver 120 relative the receiver platform 110. In particular, the set of undercut sections—defined by the set of fixed rails 114—can be configured to seat over complementary angled faces (e.g., angled side walls) of the base section 122. The base section 122 can therefore slide onto the receiver platform 110, from a loading side of the receiver platform 110, within a constrained slot—defining dimensions corresponding to the base section 122—defined by the mounting surface, the set of fixed rails 114, and the set of undercut sections.

For example, the receiver platform 110 can include: a first fixed rail 114 extending from a first side of the mounting surface and defining a first undercut section facing a central horizontal axis extending along a length of the mounting surface; and a second fixed rail 114 extending from a second side of the mounting surface—opposite the first side—and defining a second undercut section facing the central horizontal axis of the mounting surface. In this example, the base section 122 of the sample receiver 120 can define: an upper surface of a first width; a base surface—opposite the upper surface—of a second width exceeding the first width; a first beveled face (e.g., a first side of the base section 122) extending outward from the upper surface to the base surface on a first side of the base section 122; and a second beveled face (e.g., a second side of the base section 122) extending outward from the upper surface to the base surface on a second side of the base section 122 opposite the first side.

In a loaded configuration: the first undercut section of the first fixed rail 114 can be configured to mate with the first beveled face of the sample receiver 120; and the second undercut section of the second fixed rail 114 can be configured to mate with the second beveled face of the sample receiver 120. Therefore, in this example, in a loaded configuration: the base surface of the sample receiver 120 can mate with the mounting surface of the receiver platform 110; the first undercut section of the first fixed rail 114 can seat over the first beveled face of the base section 122 to form complementary mated faces (e.g., complementary 45-degree angle faces); and the second undercut section of the first fixed rail 114 can seat over the second beveled face of the base section 122 to form complementary mated faces (e.g., complementary 45-degree angle faces);

Additionally, in one implementation, the receiver platform 110 can further include a spring element 116 arranged proximal the mounting surface and configured to drive the receiver platform 110 against the sample receiver 120 in order to maximize contact between the mounting surface and a lower surface—opposite the upper surface—of the sample receiver 120, and thereby promote increased heat transfer between the sample receiver 120 and the receiver platform 110.

In particular, in this implementation, the base section 122 can define the upper surface and a lower surface opposite the upper surface, and the set of fixed rails 114 can be configured to retain the lower surface of the base section 122 against the mounting surface of the receiver platform 110. The upper assembly 102 can further include a spring element 116: arranged proximal the mounting surface; and configured to drive the mounting surface against the lower surface to maximize a contact area between the mounting surface and the lower surface and constrain the base section 122 between the mounting surface and the set of fixed rails 114.

### 3.2 Insulator Section

In one implementation, the system 100 includes an insulator section 140 arranged between the upper assembly 102 and the lower assembly 104 and configured to thermally isolate the upper assembly 102 from the lower assembly 104 and thus reduce heat transfer between these assemblies. In particular, the system 100 can include an insulator section 140: including a material exhibiting a conductivity less than a threshold conductivity (e.g., a relatively low conductivity); interposed between the set of positioner stages 130 and the receiver platform 110; and configured to thermally isolate the upper assembly 102 from the lower assembly 104, thereby preventing and/or minimizing heat transfer between the upper and lower assemblies.

In this implementation, the insulator section 140 can be rigidly coupled to the receiver platform 110 (e.g., arranged above the insulator section 140) and movably coupled to the lower assembly 104 (e.g., arranged below the insulator section 140), such that the set of positioner stages 130 of the lower assembly 104 can cooperate to reposition the insulator section 140, relative the lower assembly 104, in order to locate the sample holder 124—and the sample loading region of the sample grid retained within the grid receptacle 126—in a particular position and/or sequence of positions.

Generally, the insulator section 140 can be formed of a material exhibiting relatively low-conductivity in order to minimize heat transfer between the upper and lower assemblies during operation. For example, the set of positioner stages 130 may generate heat during actuation, thereby triggering minute movements or motion of components of the system 100. Therefore, the system 100 can include a thermal insulator arranged between the set of positioner stages 130 and the upper assembly 102 and configured to prevent and/or limit transfer of heat—generated during actuation of the set of positioner stages 130—into the upper assembly 102 and thus: minimize unintentional motion of components (e.g., the sample receiver 120, the sample holder 124) of the upper assembly 102 due to heat transfer into the upper assembly 102; and enable accurate and stable positioning of the sample holder 124 regardless of heat generation in the lower assembly 104.

### 3.3 Lower Assembly: Positioner Stages

Generally, the lower assembly 104 includes a set of positioner stages 130 configured to drive the sample holder 124 to a particular position or sequence of positions in order to locate the sample loading region of the sample grid—retained in the grid receptacle 126 and preloaded with a sample—into a target sample position or over a sequence of target sample positions.

In one implementation, the set of positioner stages 130 can cooperate to translate the sample holder 124 in x, y, and z-coordinate directions and to rotate the sample holder 124 about a fixed rotational axis. For example, the lower assembly 104 can include a 3-axis nanopositioner including a set of nanopositioner stages 130 (e.g., piezo nanopositioner stages 130).

In particular, in this implementation, the set of positioner stages 130 can include: a first subset of positioner stages 130 (e.g., a first and/or second positioner stage) configured to drive the sample holder 124 along a dynamic (e.g., variable) x-axis in a first direction and a second direction opposite the first direction, the dynamic x-axis parallel a horizontal plane defined by the mounting surface; a second subset of positioner stages 130 (e.g., a third and/or fourth positioner stage) configured to drive the sample holder 124 along a dynamic (e.g., variable) y-axis—perpendicular and coplanar the x-axis—in a third direction and a fourth direction opposite the third direction; and a third subset of positioner stages 130 (e.g., a fifth and/or sixth positioner stage) configured to drive the sample holder 124 along a dynamic (e.g., variable) z-axis in a fifth direction and a sixth direction opposite the fifth direction, the dynamic z-axis perpendicular the x-axis and the y-axis. Further, the set of positioner stages 130 can include a fourth subset of positioner stages 130 (e.g., a seventh positioner stage) configured to drive rotational motion of the sampler holder about a fixed rotational axis parallel to the z-axis. The fourth subset of positioner stages 130 can therefore be configured to rotate the sample holder 124 about the fixed rotational axis when the dynamic z-axis aligns with the fixed rotational axis.

In one example, the set of positioner stages 130 can include: a set of lower positioner stages 130 configured to drive lateral and/or longitudinal movement of the upper assembly (and/or the set of lower positioner stages 130 and/or the insulator section 140) to move the sample holder 124 along the dynamic x-, y-, and/or z-axes, such as during relocation of the upper assembly 104 to the loading position—in order to engage the fixed pin 154 of the positioner arm 150—and/or to the target detection position; a set of upper positioner stages 130—arranged above the set of lower positional stages 130 and below the upper assembly 104 and/or the insulator section 140—configured to drive lateral and/or longitudinal movement of the sample holder 124 to align the grid receptacle 126 with the electron beam pathway, such as during the detection period; and a rotational positioner stage 130—interposed between the set of lower positioner stages 130 and the set of upper positioner stages 130—configured to drive rotational motion of the sample holder 124 about the fixed rotational axis.

For example, the set of lower positioner stages 130 can include: a subset of “x-axis” positioner stages configured to selectively drive the upper assembly 104 in the first and second directions to move the sample holder 124 along the dynamic x-axis; a subset of “y-axis” positioner stages configured to selectively drive the upper assembly 104 in the third and fourth directions to move the sample holder 124 along the dynamic y-axis; and a subset of “z-axis” positioner stages configured to selectively drive the upper assembly 104 in the fifth and sixth directions to move the sample holder 124 along the dynamic z-axis. In this example, the set of lower positioner stages 130 can also include: a subset of “x-axis” positioner stages configured to selectively drive the sampler holder 124 in the first and second directions along the dynamic x-axis; a subset of “y-axis” positioner stages configured to selectively drive the sample holder 124 in the third and fourth directions along the dynamic y-axis; and a subset of “z-axis” positioner stages configured to selectively drive the sample holder 124 in the fifth and sixth directions along the dynamic z-axis.

The set of positioner stages 130 can therefore cooperate to drive the sampler holder in directions along the dynamic x-, y-, and z-axes to locate the sample loading region of the sample grid in a target detection position intersecting the fixed rotational axis and an electron beam pathway—extending from an outlet of the electron emitter 190 to the sample target detection position—defined by electron optics. Then, the system 100 can trigger the electron emitter 190 to output an electron beam along the electron beam pathway to initiate analysis of the sample.

In one example, the set of positioner stages 130 can be configured to: drive the sample receiver 120 to an initial sequence of positions during the loading period to drive the recess 118 about the fixed pin 154 and locate the receiver platform 110 in a loading position; and drive the sample receiver 120 to the sequence of positions—such as from the loading position to the target detection position—to locate the sample specimen, pre-loaded in the grid receptacle 126 of the sample holder 124, in the target detection position.

Further, the set of positioner stages 130 can cooperate to maintain the sample loading region within the target detection position and rotate the sample holder 124 about the rotational axis to enable detection of the sample at various angular positions.

### 3.4 Cooling Assembly

The system 100 can include a cooling assembly 106 thermally-coupled to the sample holder 124 and configured to regulate temperature of the sample holder 124 down to within a target temperature range defined for the sample holder 124 during the detection period.

In one implementation, the cooling assembly 106 includes: a storage vessel 174 containing a volume of coolant (e.g., liquid nitrogen); a cold finger 170 (e.g., a copper bar) defining a first end inserted in the volume of coolant within the storage vessel 174 and defining a second end external and located above the storage vessel 174; a vacuum pipe 172 encompassing a portion of the cold finger 170 external the storage vessel 174, configured to maintain a vacuum within the vacuum pipe 172, and configured to prevent unintentional contact of the cold finger 170 with components of the system 100 and thereby prevent unintentional heat transfer between the cold finger 170 and these components; and a cooling braid 160 thermally-coupled to the cold finger 170 and to the sample holder 124 and configured to extract heat from the sample holder 124 to cool the sample holder 124 to temperatures within the target temperature range. Therefore, the cooling braid 160 can be configured to exhibit relatively high thermal conductivity in order to facilitate heat transfer from the sample holder 124 into the cooling braid 160.

For example, the cooling assembly 106 can include: a storage Dewar containing a volume of liquid nitrogen cooled to a target coolant temperature and arranged outside the vacuum housing 180; a copper rod including a lower end submerged in the volume of liquid nitrogen and an upper end extending out of the storage Dewar and into the vacuum housing 180 (e.g., toward the upper assembly 102); a sealed pipe encompassing an upper portion of the copper rod extending outside of the storage Dewar; and a copper braid defining a first end in physical contact with the upper end of the copper rod and therefore thermally-coupled to the copper rod and a second end in physical contact with the receiver platform 110—physically coupled to the sample receiver 120—and therefore thermally-coupled to the sample holder 124. In this example, the copper braid can be configured to exhibit an elastic modulus below a threshold elastic modulus at temperatures within the target sample temperature range (e.g., between −140 degrees Celsius and −180 degrees Celsius).

In this example, the copper rod is cooled via direct contact with the volume of liquid nitrogen. The copper rod then cools the cooling braid 160. Therefore, when coupled to the receiver platform 110, the cooling braid 160—exhibiting a substantially lower temperature than the receiver platform 110—extracts heat from the receiver platform 110, cooling the sample receiver 120 coupled to the receiver platform 110. The cooling assembly 106 therefore generates a high-temperature differential between the receiver platform 110 and the cooling braid 160 in order to induce heat transfer from the receiver platform 110 into the cooling braid 160—and therefore from the sample receiver 120 into the receiver platform 110—via conduction.

In one implementation, the cooling assembly 106 can be configured to: enable cooling of the sample receiver 120 at a target cooling rate, such as in order to cool the sample receiver 120—including the sample holder 124 loaded with the sample—to temperatures within the target sample temperature range within a target cooling duration; ground the sample during the detection period via the cooling braid 160; and enable rotation of the upper assembly 102 about the fixed rotational axis during the detection period—to enable detection of the sample from various detection angles—without crossing a pathway of the ion beam (or “beam pathway”).

### 3.4.1 Cooling Braid

Generally, the cooling braid 160 is: coupled to the primary assembly-such as at the upper assembly 102 or the lower assembly 104—at a target contact region defining a contact area exceeding a threshold contact area; and configured to communicate thermal energy from the primary assembly at a target cooling rate corresponding to the contact area.

In one implementation, the cooling braid 160 can be formed of a conductive material configured to cool the sample receiver 120—by removing heat from the sample receiver 120 via conduction—at a target cooling rate. For example, the cooling braid 160 can be formed of a copper material (e.g., an oxygen-free copper, a copper alloy). The cooling braid 160 can therefore be configured to exhibit a high rate of thermal conductivity and thus reduce a cooling duration for cooling the sample receiver 120—and the sample holder 124 loaded with the sample in the grid receptacle 126—to within the target sample temperature range, thereby enabling increased throughput of sample analysis. Additionally, the cooling braid 160 can be configured to ground an electrical charge accumulated on the sample holder 124 due to actuation of the electron emitter 190 and contact of the electron beam with the sample specimen contained in the grid receptacle 126.

Additionally, in one implementation, the cooling braid 160 can be formed of a flexible material. For example, the cooling braid 160 can be formed of a material including copper and a material softener (e.g., lead) configured to increase flexibility of the cooling braid 160. In particular, in this implementation, the cooling braid 160 can be configured to exhibit flexibility at temperatures within the target sample temperature range (e.g., −150 degrees Celsius), such that the cooling braid 160 exhibits relatively high resistance to fatigue at temperatures within the target sample temperature range.

Therefore, the cooling braid 160 can be configured to exhibit a relatively low elastic modulus—such as below a threshold elastic modulus—at temperatures within the target sample temperature range, and thereby be configured to exhibit minimal fatigue at temperatures within the target temperature range. Therefore, by forming the cooling braid 160 of a material exhibiting flexibility at these low target temperatures, the cooling braid 160 can be configured to: exhibit a reduced risk of breakage and/or generation of microfractures in the cooling braid 160; endure temperature cycling over a threshold quantity of cycles, thereby enabling increased throughput of sample analysis, such as without replacement or repairing of the cooling braid 160 due to breakage; limit reduction in thermal conductivity of the cooling braid 160 over time due to generation of these microfractures and thereby limit increases in cooling duration for the sample receiver 120 over time; and reduce costs associated with breakage and/or replacement of the cooling bread.

Further, by including a cooling braid 160 formed of a flexible material, the cooling braid 160 can be configured to limit and/or prevent application of force (e.g., torque)—such as exceeding a threshold force—onto the set of positioner stages 130. In particular, rather than including a rigid cooling braid 160 coupled to the sample receiver 120—which may exert a torque on the sample receiver 120 and/or set of positioner stages 130, and therefore reduce accuracy of positioning of the sample holder 124 during detection—the system 100 can include a flexible cooling braid 160 configured to exert no torque or a minimal torque on the upper and/or lower assemblies. For example, the cooling braid 160 can be configured to: exhibit an elastic modulus below a threshold elastic modulus at temperatures within the target sample temperature range; and thereby exert a torque—less than a threshold torque—on the upper assembly 102 during motion of the upper assembly 102 responsive to actuation of the set of positioner stages 130, such as during the loading period and/or during relocation of the grid receptacle 126 to the target detection position.

Additionally, in another implementation, the cooling braid 160 can be configured to exhibit a target braid length configured to balance resistance of the cooling braid 160 to fatigue and a rate of cooling of the sample receiver 120. In particular, in this implementation, the cooling braid 160 can exhibit a braid length within a target length range defining a lower threshold length and an upper threshold length. At the lower threshold length, the cooling braid 160 can be configured to exhibit at least a minimum resistance to fatigue and a relatively high rate of cooling of the sample receiver 120. However, at the upper threshold length, the cooling braid 160 can be configured to exhibit a relatively high resistance to fatigue and at least a minimum rate of cooling of the sample receiver 120. Therefore, by including the cooling braid 160 exhibiting a braid length within the target length range, the cooling braid 160 can be configured to exhibit relatively high flexibility—such as represented by the elastic modulus at temperatures within the target sample temperature range—and enable a relatively high cooling rate of the sample receiver 120 via heat transfer between the cold finger 170 and the sample receiver 120.

Further, in this implementation, the cooling braid 160—exhibiting a braid length within this target length range—can be configured to enable a target amount of rotation of the sample receiver 120, without exhibiting breakage or crossing the electron beam pathway. For example, the cooling braid 160 can define a braid length configured to: enable cooling of the sample receiver 120 at a target cooling rate; enable temperature cycling—such as to temperatures below −150 degrees Celsius—of the cooling braid 160 over a target quantity of cycles (e.g., without replacement of the cooling braid 160); and enable 200-degrees of rotation of the sample receiver 120.

### 3.4.2 Cooling Braid: Contact Area

In one implementation, the cooling braid 160 is: coupled to the primary assembly—including the upper and lower assemblies—at a target contact region defining a contact area exceeding a threshold contact area; and configured to communicate thermal energy from the primary assembly at a target cooling rate corresponding to the contact area.

In particular, in this implementation, the cooling braid 160 can be physically coupled to the upper and/or lower assembly 104 at a target contact region defining a contact area exceeding a threshold area. In particular, in this implementation, the contact area can be configured to exceed the threshold area, such that the cooling braid 160 can be configured to cool the sample specimen-loaded within the sample holder 124 at the target cooling rate.

For example, the cooling braid 160 can define a first end coupled to the cooling finger and a second end coupled to the sample receiver 120. In this example, the second end of the cooling braid 160 can include a flat surface defining a first surface area and configured to contact a mating surface (e.g., a flat surface) of the sample receiver 120. Therefore, the flat surface of the second end of the cooling braid 160 can be configured to mate approximately flush with the mating surface of the sample receiver 120. The flat surface of the second end of the cooling braid 160 and the mating surface of the sample receiver 120 can therefore cooperate to exhibit a contact area exceeding the threshold contact area.

More specifically, in this example, the receiver platform 110 can define a mating surface of a first area, and the cooling braid 160 can define a flat surface (e.g., opposite an end contacting the cold finger 170) of a second area contacting the mating surface, to define a contact area—between the flat surface and the mating surface—exceeding a threshold contact area. The cooling braid 160 can then be configured to communicate thermal energy from the upper assembly 102—via the receiver platform 110 contacting the sample receiver 120—into the cold finger 170 to cool the sample specimen to temperatures within the target sample temperature range at a cooling rate corresponding to (e.g., proportional) the contact area via direct contact between the flat surface and the mating surface.

### 3.4.2.1 Contact Area: Upper Assembly

In one implementation, the cooling braid 160 can be physically coupled directly to the upper assembly 102, such as at a mating surface defined by the sample receiver 120. In this implementation, the cooling assembly 106 can be configured to limit cooling to components of the upper assembly 102—including the sample receiver 120, the sample holder 124, and the sample loaded within the grid receptacle 126 of the sample holder 124—thereby reducing a cooling duration required for cooling the sample to temperatures within the target sample temperature range (e.g., between −120 degrees Celsius and −180 degrees Celsius).

Therefore, in this implementation, the system 100 can include the insulator section 140 (as described above) configured to thermally isolate the upper assembly 102 from the lower assembly 104. For example, the system 100 can include the insulator section 140: formed of a material exhibiting a conductivity less than a threshold conductivity; interposed between the set of positioner stages 130 and the receiver platform 110; and configured to thermally isolate the upper assembly 102 from the lower assembly 104.

Further, in this implementation, the cooling braid 160 can be formed of a flexible material (as described above), in order to enable rotation of the upper assembly 102—without exertion of force on the upper assembly 102 by the cooling braid 160 and/or crossing of the beam pathway by the cooling braid 160—and relatively low fatigue of the cooling braid 160 due to temperature cycling over time.

For example, the primary assembly includes the upper assembly 102—including the sample receiver 120 and the receiver platform 110—and the lower assembly 104 flexibly coupled to the upper assembly 102 and including the set of positioner stages 130. In this example, the cooling braid 160 is: coupled to the upper assembly 102 at the receiver platform 110; and configured to communicate thermal energy from the receiver platform 110 into the cold finger 170 to cool the receiver platform 110, such as via direct contact between the receiver platform 110 and the cold finger 170 and direct contact between the receiver platform 110 and the sample holder 124. Additionally, in this example, the cooling braid 160 can: exhibit an elastic modulus below a threshold elastic modulus at temperatures within the target sample temperature range; and be configured to exert a torque less than a threshold torque on the upper assembly 102 during motion of the upper assembly 102 responsive to actuation of the set of positioner stages 130.

### 3.4.2.2 Contact Area: Lower Assembly

In one variation, the cooling braid 160 can be physically coupled to the lower assembly 104, such as at a mating surface defined by the set of positioner stages 130.

In this variation, the cooling assembly 106 can be configured to cool components of both the lower and upper assemblies-including the set of positioner stages 130, the sample receiver 120, the sample holder 124, and the sample loaded within the grid receptacle 126 of the sample holder 124—to temperatures within the target sample temperature range. Therefore, in this implementation, the system 100 can omit the insulator section 140 in order to increase the cooling rate of the sample receiver 120 and sample contained in the sample holder 124, thereby reducing a footprint of the system 100.

In particular, in this variation, the cooling braid 160 is: coupled to the lower assembly 104 at the set of positioner stages 130; and configured to communicate thermal energy from the set of positioner stages 130 into the cold finger 170 to cool the set of positioner stages 130—thereby restricting movement of the set of positioner stages 130 during the detection period in which the electron emitter 190 generates and accelerates an electron beam along the electron beam pathway—thus cooling the upper assembly 102 (e.g., in contact with the set of positioner stages 130) and cooling the sample specimen. In particular, responsive to cooling of the set of positioner stages 130 by the cooling braid 160, the set of positioner stages 130 can communicate thermal energy from the upper assembly 102, via contact between the receiver platform 110 and the set of positioner stages 130, into the cooling braid 160 to cool the sample specimen loaded within the grid receptacle 126.

In this variation, by coupling the cooling braid 160 to the lower assembly 104 rather than the upper assembly 102, the system 100 can enable rotation of the upper assembly 102 without any interference from the cooling braid 160, such as due to application of force (e.g., torque) on the upper assembly 102 by the cooling braid 160 during positioning and/or due to crossing of the cooling braid 160 with the beam pathway during actuation of the electron emitter 190. Therefore, by coupling the cooling braid 160 to the lower assembly 104 rather than the upper assembly 102, the cooling braid 160 can exhibit reduced flexibility—thereby reducing constraints and/or costs associated with construction of the cooling braid 160—without restricting rotation of the upper assembly 102. Further, by cooling the lower assembly 104—including the set of positioner stages 130—to temperatures within the target sample temperature range prior to initiation of the detection period (e.g., via actuation of the electron emitter 190), the cooling braid 160 can be configured to restrict movement in the lower assembly 104 during the detection period and therefore restrict unintentional movement of the sample holder 124 during the detection period.

### 3.4.2.3 Cooling Braid: Material

Generally, the cooling braid 160 can be configured to communicate thermal energy from the primary assembly—including the upper assembly 102 and/or lower assembly 104—into the cold finger 170 to cool the sample specimen loaded within the grid receptacle 126. The cooling braid 160 can therefore be formed of a highly-conductive material, such that the cooling braid 160 communicates heat from the primary assembly at a target rate exceeding a threshold rate.

In one implementation, the cooling braid 160 can be formed of a set of wires—such as a group of thin, copper wires—forming a singular braid structure. In this implementation, the set of wires can be configured to exhibit a target thickness—less than a threshold thickness—such that the resulting cooling braid 160 exhibits high flexibility at relatively low temperatures including temperatures within the target sample temperature range.

Alternatively, in another implementation, the cooling braid 160 can be formed of a solid copper wire exhibiting at least a threshold ductility.

In particular, in this implementation, the cooling braid 160 can: include a solid copper wire configured to exhibit a target ductility (e.g., exceeding the threshold ductility) over a target quantity of cooling cycles; and be configured to transiently decouple from the cold finger 170 and the primary assembly (e.g., at the upper assembly 102 or lower assembly 104)—responsive to execution of the target quantity of cooling cycles—for re-processing according to an annealing process defining a target annealing temperature. For example, after a fixed quantity of cooling cycles, the cooling braid 160—formed of the solid copper wire—can be: decoupled from the cooling assembly 106 (e.g., manually decoupled by an operator); heated to a target temperature within a vacuum furnace for a target duration ductile, fully-annealed solid copper wire; and, in response to expiration of the target duration, re-coupled to the cooling assembly 106 in preparation for a next cooling cycle. In particular, in one example, the resulting cooling braid 160 can define a fully-annealed, oxygen-free electrolytic copper cooling braid 160. The cooling braid 160 can therefore be re-processed at a target frequency in order to maintain the target ductility over many cooling cycles, thereby limiting fatigue and/or damage experienced by the cooling braid 160 over time.

### 3.5 Electron Gun+Detectors

Generally, the system 100 can include an electron emitter 190 (or “electron gun”) arranged in a position and orientation relative to the sample holder 124 in the target detection position. The electron emitter 190 can be configured to transiently generate and accelerate an electron beam along the electron beam pathway—intersecting the target detection position and orthogonal the fixed rotational axis—and toward the sample region of the sample grid extending from the grid receptacle 126 of the sample holder 124. The upper assembly 102 can rotate about the rotational axis to modify the angular orientation of the sample grid relative the electron emitter 190—and thus modify an orientation of the sample grid relative the electron beam pathway—while maintaining the sample region of the sample grid within the electron beam pathway.

Further, the system 100 can include a set of detectors 192 (e.g., radial and/or longitudinal detectors) arranged about the sample holder 124 and configured to capture a set of sample data representing structural characteristics of the sample loaded in the grid receptacle 126 of the sample holder 124. For example, the system 100 can include: an X-ray detector configured to capture sample data representing X-ray characteristics—such as flux, spatial distribution, and/or spectrum—detected during a detection period for a sample; and/or an electron detector—such as a hybrid pixel detector or an active pixel detector—configured to capture images, diffraction patterns, and/or electron energy loss spectra detected during the detection period.

Additionally, in one implementation, the system 100 can include a set of thermocouples configured to record temperature data for various components of the system 100. For example, the system 100 can include a thermocouple coupled to the upper assembly 102—such as at the receiver platform 110 or sample receiver 120—configured to record a temperature of the upper assembly 102 during the cooling period. In one example, the system 100 can include a thermocouple braid (e.g., a flexible, conductive braid) coupled to the upper assembly 102 at a first end and coupled to the thermocouple at the second end. The thermocouple can then record a series of temperature readings for the upper assembly 102 during the cooling period. Then, during the cooling period, in response to a current temperature reading falling within the target sample temperature range (e.g., less than −130 degrees Celsius, less than −150 degrees Celsius, less than −180 degrees Celsius), the system 100 can automatically initiate the detection period and trigger actuation of the electron emitter 190.

In this implementation, the system 100 can further include: a set of low-current data lines coupled to the set of thermocouples within the vacuum housing 180 and configured to output a signal—indicative of a temperature reading—from the set of thermocouples; and a set of higher-current control lines coupled to the set of positioner stages 130 within the vacuum housing 180.

### 4. Variation: Positioner Arm

In one variation, the system 100 further includes a positioner arm 150 configured to transiently engage the receiver platform 110 during loading of the sample receiver 120 onto the receiver platform 110 during a loading period.

In this variation, the positioner arm 150 can be rigidly mounted to a positioner base 152 of the lower assembly 104. The positioner arm 150 can be configured to transiently engage a recess 118 in the mounting surface of the receiver platform 110 to constrain motion of the receiver platform 110 during the loading period. In particular, the positioner arm 150 can be configured to: accept forces applied to the receiver platform 110 by the sample receiver 120—including the sample holder 124 loaded with a sample grid within the grid receptacle 126—during the loading period; and therefore stabilize (e.g., constrain motion of) the receiver platform 110 during the loading period while preventing distribution of these forces into the set of positioner stages 130 flexibly mounted to the positioner base 152. The positioner arm 150 can be configured to similarly engage the receiver platform 110 during unloading of the sample receiver 120 from the receiver platform 110 during an unloading period to stabilize the receiver platform 110.

In particular, the receiver platform 110 can slidably receive the sample receiver 120 on the mounting surface, between the set of fixed rails 114, as described above. The spring element 116—arranged proximal the mounting surface—can drive the receiver platform 110 upward against the sample receiver 120, to drive the mounting surface against the lower surface of the sample receiver 120 and maximize a contact area between the mounting surface and the lower surface, thereby maximizing heat transfer via conduction between these surfaces. By driving the mounting surface against the lower surface of the sample receiver 120, the spring element 116 can drive the sample receiver 120 toward and against the set of fixed rails 114—therefore increasing friction between surfaces of the receiver platform 110 and the sample receiver 120—and thus increasing an amount of force required to drive the sample receiver 120 across the mounting surface during loading and unloading of the sample receiver 120 from the receiver platform 110. The system 100 can therefore include the positioner arm 150 to constrain motion of the receiver platform 110 during application of this required amount of force on the sample receiver 120 during the loading and/or unloading periods.

In one implementation, the positioner arm 150 can define: a fixed support mounted to the positioner base 152 at a first end; a shelf section extending horizontally outward from a second end of the fixed support—opposite and above the first end within the housing 180—toward the receiver platform 110; and a fixed pin 154 extending downward from the shelf section and defining a fixed pin 154 location. In this implementation, the receiver platform 110 can define a recess 118 arranged on a side of the mounting surface proximal the positioner arm 150. The fixed pin 154 and the recess 118 can be configured to exhibit corresponding geometries, such that the fixed pin 154 can nest within the recess 118 and retain the recess 118 about the fixed pin 154 (e.g., without slipping of the recess 118 off of the fixed pin 154 away from the shelf section) regardless of forces applied to the receiver platform 110 by the sample receiver 120 during the loading and unloading period. The set of stage positioners can be configured to drive the receiver platform 110 toward the shelf section to drive the recess 118 toward the fixed pin 154 location and seat the fixed pin 154 within the recess 118. The fixed pin 154 can therefore be configured to transiently nest within the recess 118 to constrain motion of the receiver platform 110 and/or the set of positioner stages 130 due to application of forces on the receiver platform 110, by the sample receiver 120, during the loading and/or unloading period.

For example, the positioner arm 150 can define a fixed pin 154 (e.g., a cylindrical boss or rod) located in a fixed pin 154 location and exhibiting a first cross-section. The receiver platform 110 can: be configured to receive the sample receiver 120 on a first end of the mounting surface; and define a recess 118 arranged proximal a second end of the mounting surface—opposite the first end—and exhibiting a second cross-section, the first cross-section of the fixed pin 154 configured to nest within the second cross-section of the receiver platform 110. In this example, at a start of the loading period, the set of positioner stages 130 can cooperate to: drive the receiver platform 110 toward the shelf section of the positioner arm 150 to locate the recess 118 below the fixed pin 154 location and coaxial the fixed pin 154; and drive the receiver platform 110 upward, to drive the recess 118 upward toward the fix pin location, to seat the fixed pin 154 within the recess 118. Then, an operator and/or automated sample loader may: locate the sample receiver 120 on the first end of the receiver platform 110; and apply a loading force (e.g., a horizontal force) on the sample receiver 120 to drive the sample receiver 120 across the mounting surface and into the loaded configuration. As the sample receiver 120 slides along the mounting surface toward the loaded configuration, the spring element 116 can drive the mounting surface upward and against the sample receiver 120 to increase contact and heat transfer (e.g., via conduction) between these surfaces. The operator and/or automated sample loader may therefore apply a loading force configured to overcome forces applied to the sample receiver 120 due to actuation of the spring element 116. The fixed pin 154, the fixed support, and the positioner base 152 can cooperate to accept this loading force, rigidly retain the fixed pin 154 in the fixed pin 154 location, and therefore constrain motion of the receiver platform 110 via retention of the fixed pin 154 within the recess 118.

The positioner arm 150 can therefore constrain unintentional motion of the receiver platform 110 and/or the set of positioner stages 130, flexibly coupled to the receiver platform 110, during loading and unloading of the sample receiver 120. Further, by enabling application of high loading forces on the sample receiver 120 and/or receiver platform 110—without unintentional motion of the receiver platform 110—the positioner arm 150 can enable application (e.g., by the spring element 116) of a relatively high spring force on the mounting surface against the sample receiver 120, therefore enabling increased contact between surfaces of the receiver platform 110 and the sample receiver 120 and promoting increased heat transfer via conduction between these surfaces.

For example, the system 100 can include: the spring element 116 arranged proximal the mounting surface of the receiver platform 110 configured to drive the mounting surface against a lower surface—opposite the upper surface—of the base section 122 of the sample receiver 120 to maximize a contact area between the mounting surface and the lower surface; and the positioner arm 150 rigidly mounted to the positioner base 152 and defining a fixed pin 154 configured to transiently engage the recess 118 of the receiver platform 110 to stabilize the receiver platform 110 during the loading period. The fixed pin 154 can further: define a first geometry (e.g., a first cross-section and/or depth) corresponding to a second geometry (e.g., a second cross-section and/or depth) of the recess 118; and be configured to nest within the recess 118 to constrain motion of the receiver platform 110 responsive to forces applied to the receiver platform 110 by the sample receiver 120—during loading of the sample receiver 120 onto the receiver platform 110—and by the spring element 116.

### 5. Cooling Rate+Hold Duration

In one implementation, the system 100 can be configured to: cool the sample specimen—pre-loaded in the sample grid loaded in the grid receptacle 126—to temperatures within the target sample temperature range at a target cooling rate; and maintain the sample specimen at these temperatures—within the target sample temperature range—for a target hold duration corresponding to (e.g., proportional) the target cooling rate.

Therefore, by adjusting the target cooling rate, the system 100 can similarly adjust the target hold duration for maintaining the sample specimen at temperatures within the target sample temperature range.

For example, the system 100 can be configured to receive components—such as the sample holder 124 and/or the cooling finger—of varying sizes over time in order to modify a target cooling rate and therefore the target hold duration experienced by the sample specimen loaded within the system 100.

In one example, the system 100 can include: a first sample holder 124 of a first size mounted to the base section 122 during a first time period; and a second sample holder 124 of a second size—exceeding the first size—mounted to the base section 122 during a second time period. In this example, the cooling braid 160 can be configured to: during the first time period, communicate thermal energy from the primary assembly (e.g., at the upper or lower assembly 104) into the cold finger 170 to cool the sample specimen to temperatures within the target sample temperature range at a first cooling rate corresponding to the first size; and, during the second time period, communicate thermal energy from the primary assembly into the second cold finger 170 to cool the sample specimen to temperatures within the target sample temperature range at a second cooling rate—less than the first cooling rate—corresponding to the second size. The cooling assembly 106 can therefore be configured to: during the first time period, maintain the sample specimen at temperatures within the target sample temperature range for a first duration corresponding to the first cooling rate; and, during the second time period, maintain the sample specimen at temperatures within the target sample temperature range for a second duration—exceeding the first duration—corresponding to the second cooling rate.

In another example, the system 100 can include: a first cold finger 170 of a first size installed within the vacuum pipe 172 during a first time period; and a second cold finger 170 of a second size—exceeding the first size—installed within the vacuum pipe 172 during a second time period in replacement of the cold finger 170. In this example, the cooling braid 160 can be configured to: during the first time period, communicate thermal energy from the primary assembly (e.g., at the upper or lower assembly 104) into the cold finger 170 to cool the sample specimen to temperatures within the target sample temperature range at a first cooling rate corresponding to the first size; and, during the second time period, communicate thermal energy from the primary assembly into the second cold finger 170 to cool the sample specimen to temperatures within the target sample temperature range at a second cooling rate—exceeding the first cooling rate—corresponding to the second size. The cooling assembly 106 can therefore be configured to: during the first time period, maintain the sample specimen at temperatures within the target sample temperature range for a first duration corresponding to the first cooling rate; and, during the second time period, maintain the sample specimen at temperatures within the target sample temperature range for a second duration—exceeding the first duration—corresponding to the second cooling rate.

### 6. Controls

In one implementation, the system 100 can be configured to monitor a set of operating controls and selectively actuate components of the system 100 based on these operating controls.

In particular, in this implementation, the system 100—such as via a local controller—can track a set of operating controls throughout a sample cycle for a particular sample loaded in the sample holder 124, such as including: a temperature of the sample holder 124 and/or components of the upper assembly 102; a series of positions of each positioner stage in the set of positioner stages 130; and/or a series of sample positions of the sample holder 124 and/or sample grid (e.g., containing the sample). The system 100 and/or controller can then selectively actuate components of the system 100—such as the set of positioner stages 130, the electron emitter 190, and/or the set of detectors 192—based on the set of operating controls.

For example, during a sample cycle for a sample loaded in the sample holder 124, the system 100 and/or controller can: access timeseries temperature data recorded by a thermocouple coupled to the upper assembly 102 (e.g., via a thermocouple braid); access timeseries sample position data representing position of the sample, such as relative the electron beam pathway; and access timeseries stage position data representing positions of each positioner stage in the set of positioner stages 130. Then, during a loading period within the sample cycle, the system 100 can automatically trigger actuation of the set of positioner stages 130—based on timeseries stage position data and timeseries sample position data—to relocate the sample region of the sample grid from a loading position to a target detection position intersecting the electron beam pathway. Then, during a cooling period succeeding the loading period, in response to locating the sample region in the target detection position, the system 100 can maintain the sample grid in the target detection position to enable cooling of the upper assembly 102—and therefore the sample—to a temperature within the target sample temperature range. Then, based on the timeseries temperature data—such as in response to a temperature of the sample receiver 120 falling below a threshold temperature—the system 100 can: trigger the set of detectors 192—including an electron detector and an X—ray detector—to capture electromagnetic data (e.g., representing structural characteristics of the sample) during a detection period succeeding the cooling period; and trigger actuation of the electron emitter 190 to generate and accelerate an electron beam toward the sample region of the sample grid along the electron beam pathway. Finally, based on the timeseries sample position data and stage position data, the system 100 can selectively actuate the set of positioner stages 130 to locate the upper assembly 102 in the loading position for replacement of the sample grid, containing the sample, with a new sample grid containing a new sample for analysis during a subsequent sample cycle.

### 7. Operation+Maintenance

In one implementation, the system 100 can be configured to execute a sample cycle (as described above) for a single sample loaded in the sample holder 124. Alternatively, in another implementation, the system 100 can be configured to execute a sample cycle for multiple samples simultaneously loaded in the sample holder 124, such as in one or more grid receptacles 126 included in the sample holder 124.

Additionally, in one implementation, the system 100 can be configured to operate according to an operating schedule defining a series of sample cycles and maintenance cycles. For example, the system 100 can be configured to execute a series of sample cycles—such as a fixed quantity of sample cycles and/or a threshold quantity of sample cycles (e.g., exceeding a minimum quantity of sample cycles)—prior to execution of a maintenance cycle.

In this implementation, a maintenance cycle can be executed in order to extend a life of the cooling braid 160 and/or other components of the system 100. For example, the system 100 can be configured to automatically anneal the cooling braid 160 during a maintenance cycle, such as by heating the cooling braid 160 to a predefined annealing temperature, in order to return the cooling braid 160 to a “full-soft state” prior to execution of a subsequent sample cycle. In this example, the system 100 can thus automatically execute this maintenance cycle to anneal the cooling braid 160, without removal of the cooling braid 160 from within the housing 180.

Alternatively, in another example, the system 100 can be configured to alert an operator to execute a maintenance cycle. During this maintenance cycle, such as in response to completing the fixed quantity of sample cycles and/or in response to detecting a reduction in the cooling rate of the sample holder 124 during a preceding sample cycle. In this example, the operator may then: remove the cooling braid 160 from within the housing 180; anneal the cooling braid 160 to return the cooling braid 160 to the full-soft state; reinstall the cooling braid 160 within the housing 180, such as by coupling the cooling braid 160 to the cooling finger and the upper assembly 102; and confirm execution of the maintenance cycle.

The system 100 and methods described herein can be embodied and/or implemented at least in part as a machine configured to receive a computer-readable medium storing computer-readable instructions. The instructions can be executed by computer-executable components integrated with the application, applet, host, server, network, website, communication service, communication interface, hardware/firmware/software elements of a user computer or mobile device, wristband, smartphone, or any suitable combination thereof. Other systems and methods of the embodiment can be embodied and/or implemented at least in part as a machine configured to receive a computer-readable medium storing computer-readable instructions. The instructions can be executed by computer-executable components integrated by computer-executable components integrated with apparatuses and networks of the type described above. The computer-readable medium can be stored on any suitable computer readable media such as RAMs, ROMs, flash memory, EEPROMs, optical devices (CD or DVD), hard drives, floppy drives, or any suitable device. The computer-executable component can be a processor but any suitable dedicated hardware device can (alternatively or additionally) execute the instructions.

As a person skilled in the art will recognize from the previous detailed description and from the figures and claims, modifications and changes can be made to the embodiments of the invention without departing from the scope of this invention as defined in the following claims.

I claim:

1. A system comprising:
a housing configured to hold a vacuum;
a primary assembly arranged within the housing and comprising:
a sample receiver comprising:
a base section defining an upper surface; and
a sample holder rigidly mounted to the upper surface of the base section and defining a grid receptacle configured to transiently receive and retain a sample grid preloaded with a sample specimen;
a receiver platform:
defining a mounting surface configured to slidably receive and support the sample receiver; and
comprising a set of fixed rails:
extending from the mounting surface; and
configured to retain the sample receiver against the mounting surface; and
a set of positioner stages flexibly coupled to the receiver platform and configured to drive the sample holder to a sequence of positions in order to locate the sample specimen in a target detection position intersecting an electron pathway of an electron emitter;
a cooling assembly comprising:
a storage vessel containing a volume of coolant;
a cold finger:
extending through a vacuum pipe configured to hold the cold finger under vacuum; and
defining a first end submerged in the volume of coolant and a second end, opposite the first end, arranged external the storage vessel; and
a cooling braid:
comprising a flexible, conductive material;
coupled to the cold finger and to the primary assembly; and
configured to communicate thermal energy from the primary assembly into the cold finger to cool the sample specimen, loaded within the grid receptacle, to temperatures within a target sample temperature range.

2. The system of claim 1, further comprising:
the electron emitter configured to generate and accelerate an electron beam along the electron beam pathway defined by electron optics and extending from an outlet of the electron emitter to the sample detection position; and
a set of detectors configured to capture a set of sample data responsive to actuation of the electron emitter, the set of sample data representing structural characteristics of the sample loaded in the grid receptacle.

3. The system of claim 1:
wherein the receiver platform:
is configured to receive the sample receiver on the mounting surface during a loading period; and
defines a recess arranged on the mounting surface;
wherein the primary assembly further comprises a positioner base;
further comprising a positioner arm:
rigidly mounted to the positioner base; and
defining a fixed pin configured to transiently engage the recess of the receiver platform to stabilize the receiver platform during the loading period; and
wherein the set of positioner stages is flexibly mounted to the positioner base, interposed between the positioner base and the receiver platform, and configured to:
drive the sample receiver to an initial sequence of positions during the loading period to drive the recess about the fixed pin and locate the receiver platform in a loading position; and
drive the sample receiver to the sequence of positions to locate the sample specimen in the target detection position.

4. The system of claim 3:
further comprising a spring element arranged proximal the mounting surface of the receiver platform and configured to drive the mounting surface against a lower surface of the base section of the sample receiver to maximize a contact area between the mounting surface and the lower surface, the lower surface opposite the upper surface of the sample receiver; and
wherein the fixed pin:
defines a first geometry corresponding to a second geometry of the fixed pin; and
is configured to nest within the recess to constrain motion of the receiver platform responsive to forces applied to the receiver platform by the sample receiver during loading of the sample receiver onto the receiver platform and by the spring element.

5. The system of claim 1:
wherein the housing is configured to hold the vacuum within an interior volume of the housing to limit heat transfer via convection within the interior volume;
wherein the primary assembly is arranged within the interior volume of the housing; and
further comprising an ion pump:
fluidly coupled to the interior volume of the housing; and
configured to ionize and draw particles within the interior volume onto a set of charged plates of the ion pump to generate the vacuum within the interior volume.

6. The system of claim 1:
wherein the storage vessel contains the volume of coolant comprising a volume of liquid nitrogen;
wherein the cold finger comprises a copper rod; and
wherein the cooling braid comprises a copper material and exhibits an elastic modulus less than a threshold elastic modulus at temperatures within the target sample temperature range.

7. The system of claim 1, wherein the cooling braid:
is coupled to the primary assembly at a target contact region defining a contact area exceeding a threshold contact area; and
is configured to communicate thermal energy from the primary assembly at a target cooling rate corresponding to the contact area.

8. The system of claim 1:
wherein the primary assembly comprises:
an upper assembly comprising the sample receiver and the receiver platform; and
a lower assembly flexibly coupled to the upper assembly and comprising the set of positioner stages;
wherein the cooling braid is:
coupled to the upper assembly at the receiver platform; and
configured to communicate thermal energy from the receiver platform into the cold finger to cool the receiver platform; and
wherein the receiver platform is configured to communicate thermal energy from the sample receiver into the cooling braid to cool the sample specimen loaded within the grid receptacle.

9. The system of claim 8, wherein the cooling braid:
exhibits an elastic modulus below a threshold elastic modulus at temperatures within the target sample temperature range; and
is configured to exert a torque less than a threshold torque on the upper assembly during motion of the upper assembly responsive to actuation of the set of positioner stages.

10. The system of claim 8, further comprising an insulator section:
comprising a material exhibiting a conductivity less than a threshold conductivity;
interposed between the set of positioner stages and the receiver platform; and
configured to thermally isolate the upper assembly from the lower assembly.

11. The system of claim 1:
wherein the primary assembly comprises:
an upper assembly comprising the sample receiver and the receiver platform; and
a lower assembly flexibly coupled to the upper assembly and comprising the set of positioner stages;
wherein the set of positioner stages are configured to drive the sample holder to the sequence of positions in order to locate the sample specimen in the target detection position intersecting the electron pathway of the electron emitter configured to generate and accelerate an electron beam along the electron beam pathway during a detection period;
wherein the cooling braid is:
coupled to the lower assembly at the set of positioner stages; and
configured to communicate thermal energy from the set of positioner stages into the cold finger to cool the set of positioner stages and restrict movement in of the set of positioner stages during the detection period; and
wherein the set of positioner stages is configured to communicate thermal energy from the upper assembly, via contact with the receiver platform, into the cooling braid to cool the sample specimen loaded within the grid receptacle.

12. The system of claim 1, wherein the cooling braid:
comprises a solid copper wire configured to exhibit a target ductility over a target quantity of cooling cycles; and
is configured to transiently decouple from the cold finger and the primary assembly for re-processing according to an annealing process, defining a target annealing temperature, responsive to execution of the target quantity of cooling cycles.

13. The system of claim 1:
wherein the primary assembly comprises:
the sample holder of a first size mounted to the base section during a first time period; and
a second sample holder of a second size mounted to the base section during a second time period offset the first time period, the second size exceeding the first size;
wherein the cooling braid is configured to:
communicate thermal energy from the primary assembly into the cold finger to cool the sample specimen to temperatures within the target sample temperature range at a first cooling rate corresponding to the first size during the first time period; and
communicate thermal energy from the primary assembly into the second cold finger to cool the sample specimen to temperatures within the target sample temperature range at a second cooling rate corresponding to the second size during the first time period, the second cooling rate falling below the first cooling rate; and
wherein the cooling assembly is configured to:
maintain the sample specimen at temperatures within the target sample temperature range for a first duration, corresponding to the first cooling rate, during the first time period; and
maintain the sample specimen at temperatures within the target sample temperature range for a second duration corresponding to the second cooling rate during the second time period, the second duration exceeding the first duration.

14. The system of claim 1:
wherein the base section defines a lower surface opposite the upper surface;
wherein the set of fixed rails is configured to retain the lower surface of the base section against the mounting surface of the receiver platform; and
further comprising a spring element arranged proximal the mounting surface and configured to drive the mounting surface against the lower surface to maximize a contact area between the mounting surface and the lower surface and constrain the base section between the mounting surface and the set of fixed rails.

15. A system comprising:
a housing configured to hold a vacuum;
an upper assembly arranged within the housing and comprising:
a sample receiver comprising:
a base section defining an upper surface; and
a sample holder rigidly mounted to the upper surface of the base section and defining a grid receptacle configured to transiently receive and retain a sample grid preloaded with a sample specimen; and
a receiver platform:
defining a mounting surface configured to slidably receive and support the sample receiver; and
comprising a set of fixed rails:
extending from the mounting surface; and
configured to retain the sample receiver against the mounting surface;
a lower assembly arranged within the housing and comprising a set of positioner stages flexibly coupled to the receiver platform and configured to drive the sample holder to a sequence of positions in order to locate the sample specimen in a target detection position intersecting an electron pathway of an electron emitter; and
a cooling assembly thermally-coupled to the upper assembly and comprising:
a storage vessel containing a volume of coolant;
a cold finger extending through a vacuum chamber and defining a first end submerged in the volume of coolant; and
a cooling braid:
comprising a flexible, conductive material;
defining a second end coupled the cold finger and a third end coupled to the upper assembly; and
configured to communicate thermal energy from the upper assembly into the cold finger to cool the sample specimen, loaded within the grid receptacle, to temperatures within a target sample temperature range.

16. The system of claim 15, further comprising an insulator section:
interposed between the upper assembly and the lower assembly;
comprising a material exhibiting a conductivity less than a threshold conductivity; and
configured to thermally isolate the upper assembly from the lower assembly.

17. The system of claim 15:
wherein the receiver platform defines a mating surface of a first area;
wherein the third end of the cooling braid defines a flat surface of a second area contacting the mating surface to define a contact area, between the flat surface and the mating surface, exceeding a threshold contact area; and
wherein the cooling braid is configured to communicate thermal energy from the upper assembly into the cold finger to cool the sample specimen to temperatures within the target sample temperature range at a cooling rate corresponding to the contact area via contact between the flat surface and the mating surface.

18. The system of claim 15:
wherein the receiver platform:
is configured to receive the sample receiver on the mounting surface during a loading period; and
defines a recess arranged on the mounting surface;
further comprising a positioner arm:
rigidly mounted to a positioner base; and
defining a fixed pin configured to transiently engage the recess of the receiver platform to stabilize the receiver platform during the loading period; and
wherein the set of positioner stages is flexibly mounted to the positioner base, interposed between the positioner base and the receiver platform, and configured to:
drive the sample receiver to an initial sequence of positions during the loading period to drive the recess about the fixed pin and locate the receiver platform in a loading position; and
drive the sample receiver to the sequence of positions to locate the sample specimen in the target detection position.

19. The system of claim 15:
wherein the cooling assembly comprises:
the cold finger of a first size installed within the vacuum pipe during a first time period; and
a second cold finger of a second size installed within the vacuum pipe during a second time period in replacement of the cold finger, the second size exceeding the first size;
wherein the cooling braid is configured to:
communicate thermal energy from the primary assembly into the cold finger to cool the sample specimen to temperatures within the target sample temperature range at a first cooling rate corresponding to the first size during the first time period; and
communicate thermal energy from the primary assembly into the second cold finger to cool the sample specimen to temperatures within the target sample temperature range at a second cooling rate corresponding to the second size during the second time period, the second cooling rate exceeding the first cooling rate; and
wherein the cooling assembly is configured to:
maintain the sample specimen at temperatures within the target sample temperature range for a first duration, corresponding to the first cooling rate, during the first time period; and
maintain the sample specimen at temperatures within the target sample temperature range for a second duration corresponding to the second cooling rate during the second time period, the second duration exceeding the first duration.

20. A system comprising:
a housing configured to hold a vacuum;
an upper assembly arranged within the housing and comprising:
a sample receiver comprising:
a base section defining an upper surface and a lower surface opposite the upper surface; and
a sample holder rigidly mounted to the upper surface of the base section and defining a grid receptacle configured to transiently receive and retain a sample grid preloaded with a sample specimen;
a receiver platform configured to transiently receive and support the sample receiver on a mounting surface and between a set of fixed rails extending from the mounting surface; and
a spring element arranged proximal the mounting surface and configured to exert a spring force on the mounting surface to drive the mounting surface against a lower surface of the base section and drive the receiver platform upward into the set of fixed rails;
a lower assembly flexibly coupled to the upper assembling and comprising a set of positioner stages configured to transiently actuate the receiver platform to drive the sample holder to a sequence of positions in order to locate the sample specimen in a target detection position intersecting an electron pathway of an electron emitter; and
a cooling assembly thermally-coupled to the upper assembly and comprising:
a storage vessel containing a volume of coolant;
a cold finger defining a first end submerged in the volume of coolant and a second end, opposite the first end, arranged external the storage vessel; and
a cooling braid:
comprising a conductive material;
thermally-coupled to the cold finger and to the upper assembly; and
configured to communicate thermal energy from the upper assembly into the cold finger to cool the sample specimen, loaded within the grid receptacle, to temperatures within a target sample temperature range.
